(19) United States
(12) Patent Application Publication
(10) Pub. No.: US 2021/0280729 A1
(43) Pub. Date: Sep. 9, 2021

(54) PHOTOVOLTAIC DEVICES AND METHODS OF MAKING

(71) Applicant: First Solar, Inc., Tempe, AZ (US)

(72) Inventors: James Armour, Perrysburg, OH (US); Edmund Elce, Castalia, OH (US); Albert Mui, Perrysburg, OH (US); Allan Ward, Perrysburg, OH (US)

(73) Assignee: First Solar, Inc., Tempe, AZ (US)

(21) Appl. No.: 17/191,089

(22) Filed: Mar. 3, 2021

Related U.S. Application Data
(60) Provisional application No. 62/984,929, filed on Mar. 4, 2020.

(51) Int. Cl. H01L 31/05; H01L 31/18

(52) U.S. Cl. CPC H01L 31/0516; H01L 31/1876; H01L 31/0512

(57) ABSTRACT

Photovoltaic devices, and methods of making the same, are described.

### CROSS-REFERENCE TO RELATED APPLICATIONS

This application claims the benefit of U.S. Provisional Patent Application No. 62/984,929, filed under 35 U.S.C. § 111(b) on Mar. 4, 2020, and incorporated herein by reference.

### BACKGROUND

A photovoltaic device generates electrical power by converting light into electricity using semiconductor materials that exhibit the photovoltaic effect. Photovoltaic devices include a number of layers divided into a plurality of photovoltaic cells. Each photovoltaic cell can convert a light source, such as sunlight, into electrical power and can be connected in series with one or more adjacent cells. Accordingly, current generated by adjacent cells can flow through each of the photovoltaic cells.

Improving bussing between current collection portions of the photovoltaic device is important for efficient and durable operation of the device.

### BRIEF DESCRIPTION OF THE DRAWINGS

FIG. 1 schematically depicts a photovoltaic device according to one or more embodiments shown and described herein;

FIG. 2 schematically depicts a cross-sectional view along 2-2 of the photovoltaic device of FIG. 1 according to one or more embodiments shown and described herein;

FIG. 3 schematically depicts a substrate according to one or more embodiments shown and described herein;

FIG. 4 schematically depicts a photovoltaic device according to one or more embodiments shown and described herein;

FIG. 5 schematically depicts a cross-sectional view along 5-5 of the photovoltaic device of FIG. 1 according to one or more embodiments shown and described herein;

FIG. 6 schematically depicts a photovoltaic device according to one or more embodiments shown and described herein;

FIG. 7 schematically depicts a photovoltaic device according to one or more embodiments shown and described herein;

FIG. 8 schematically depicts a back view of a photovoltaic device; and

FIG. 9 a flow diagram illustrating a method for manufacturing a photovoltaic device.

### DETAILED DESCRIPTION

Photovoltaic devices can be formed by deposition of various semiconductor materials and electrode layers as thin (generally recognized in the art as less than 10 microns) film layers on a glass substrate. The substrate can then undergo various processing steps, including laser scribing processes, to define and isolate individual photovoltaic cells, define a perimeter edge zone around the photovoltaic cells, and to connect the photovoltaic cells in series. These steps can result in generation of a plurality of individual photovoltaic cells defined within the physical edges of the substrate.

One method for collecting the current from a photovoltaic device is with a bus system on a back support of the photovoltaic device. The bus system can include bus bars and bus members. The bus members can be attached at opposite longitudinal ends of the back support, respectively. The bus member can cross over and attach to the bus bars to collect the current from latch cells. The photovoltaic device can include one or more latch cells, which can be the photovoltaic cell at the furthest most positive or negative end of the string of photovoltaic cells. The latch cells can serve as a collection point of the electrical current from the photovoltaic device for interfacing with outside leads or connections through the bus members. The bus member can be separated in a junction box where leads are connected to separated ends of the bus member. There can be one or more positive and one or more negative latch cells for the photovoltaic device depending on the desired cell alignment (the photovoltaic cells can be linked in parallel or in series with external bussing, which can be part of a low voltage design). The leads can provide a means to connect the photovoltaic device to a load, other cells, a grid, and so forth.

The present technology improves reliability, flexibility, and durability of current collecting portions of photovoltaic devices to improve performance of photovoltaic devices. For example, a photovoltaic device can be divided into multiple cell configurations that permit for a lower voltage output from the photovoltaic device at a higher current.

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

All documents, including patents, patent applications, and scientific literature cited in this detailed description are incorporated herein by reference, unless otherwise expressly indicated. Where any conflict or ambiguity may exist between a document incorporated by reference and this detailed description, the present detailed description controls.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

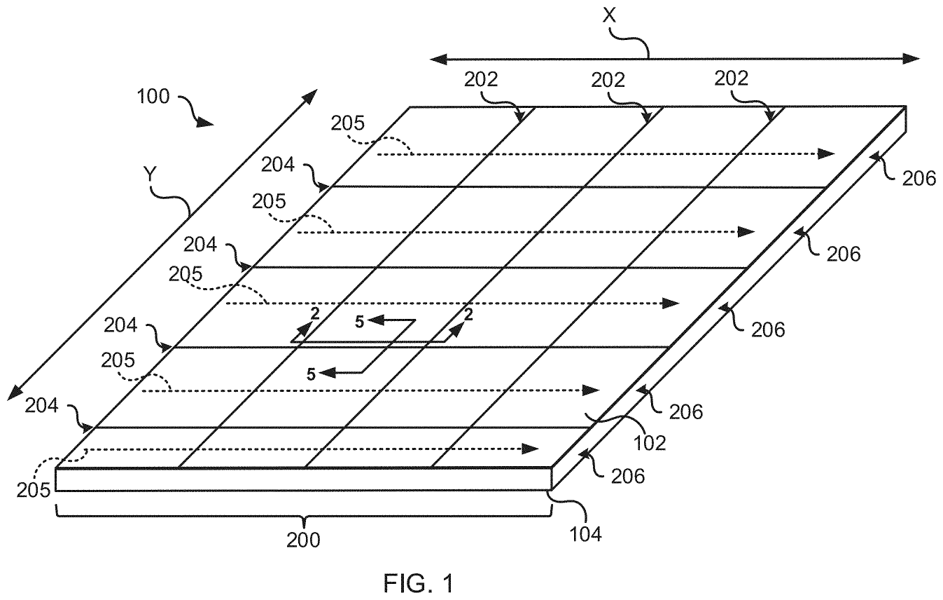

Referring now to FIG. 1, an embodiment of a photovoltaic device 100 is schematically depicted. The photovoltaic device 100 can be configured to receive light and transform light into electrical signals, e.g., photons can be absorbed from the light and transformed into electrical signals via the photovoltaic effect. Accordingly, the photovoltaic device 100 can define an energy side 102 configured to be exposed to a light source such as, for example, the sun. The photovoltaic device 100 can also define an opposing side 104 offset from the energy side 102 such as, for example, by a plurality of material layers. It is noted that the term “light” can refer to various wavelengths of the electromagnetic spectrum such as, but not limited to, wavelengths in the ultraviolet (UV), infrared (IR), and visible portions of the electromagnetic spectrum. “Sunlight,” as used herein, refers to light emitted by the sun.

The photovoltaic device 100 can include a plurality of layers disposed between the energy side 102 and the opposing side 104. As used herein, the term “layer” refers to a thickness of material provided upon a surface. Each layer can cover all or any portion of the surface. In some embodiments, the layers of the photovoltaic device 100 can be divided into an array of photovoltaic cells 200. For example, the photovoltaic device 100 can be scribed according to a plurality of serial scribes 202 and a plurality of parallel scribes 204. The serial scribes 202 can extend along a length Y of the photovoltaic device 100 and demarcate the photovoltaic cells 200 along the length Y of the photovoltaic device 100. The serial scribes 202 can be configured to connect neighboring cells of the photovoltaic cells 200 serially along a width X of the photovoltaic device 100. Serial scribes 202 can form a monolithic interconnect of the neighboring cells, i.e., adjacent to the serial scribe 202. The parallel scribes 204 can extend along the width X of the photovoltaic device 100 and demarcate the photovoltaic cells 200 along the width X of the photovoltaic device 100. Under operations, current 205 can predominantly flow along the width X through the photovoltaic cells 200 serially connected by the serial scribes 202. Under operations, parallel scribes 204 can limit the ability of current 205 to flow along the length Y. Parallel scribes 204 are optional and can be configured to separate the photovoltaic cells 200 that are connected serially into groups 206 arranged along length Y. Accordingly, the serial scribes 202 and the parallel scribes 204 can demarcate the array of the photovoltaic cells 200.

Referring still to FIG. 1, the parallel scribes 204 can electrically isolate the groups 206 of photovoltaic cells 200 that are connected serially. In some embodiments, the groups 206 of the photovoltaic cells 200 can be connected in parallel such as, for example, via electrical bussing. Optionally, the number of parallel scribes 204 can be configured to limit a maximum current generated by each group 206 of the photovoltaic cells 200. In some embodiments, the maximum current generated by each group 206 can be less than or equal to about 200 milliamps (mA) such as, for example, less than or equal to about 100 mA in one embodiment, less than or equal to about 75 mA in another embodiment, or less than or equal to about 50 mA in a further embodiment.

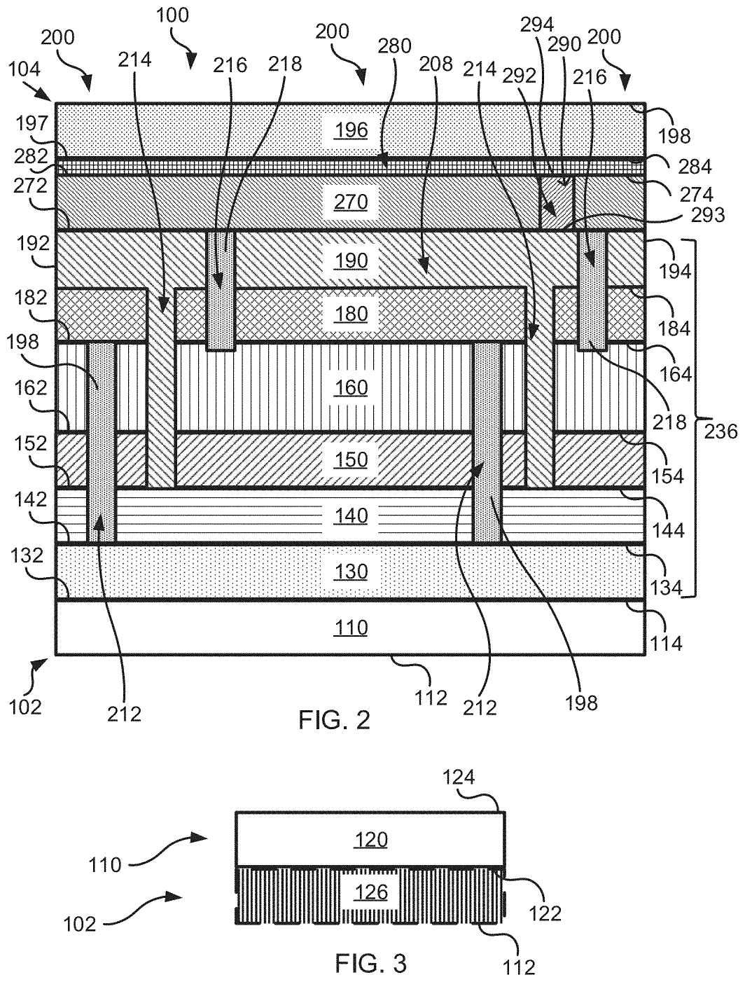

Referring collectively to FIGS. 1 and 2, the layers of the photovoltaic device 100 can include a substrate 110 configured to facilitate the transmission of light into the photovoltaic device 100. The substrate 110 can be disposed at the energy side 102 of the photovoltaic device 100. Referring now to FIGS. 2 and 3, the substrate 110 can have a first surface 112 substantially facing the energy side 102 of the photovoltaic device 100 and a second surface 114 substantially facing the opposing side 104 of the photovoltaic device 100. One or more layers of material can be disposed between the first surface 112 and the second surface 114 of the substrate 110.

Referring to FIG. 3, the substrate 110 can include a transparent layer 120 having a first surface 122 substantially facing the energy side 102 of the photovoltaic device 100 and a second surface 124 substantially facing the opposing side 104 of the photovoltaic device 100. In some embodiments, the second surface 124 of the transparent layer 120 can form the second surface 114 of the substrate 110. The transparent layer 120 can be formed from a substantially transparent material such as, for example, glass. Suitable glass can include soda-lime glass, or any glass with reduced iron content. The transparent layer 120 can have any suitable transmittance, including about 250 nm to about 1,300 nm in some embodiments, or about 250 nm to about 950 nm in other embodiments. The transparent layer 120 may also have any suitable transmission percentage, including, for example, more than about 50% in one embodiment, more than about 60% in another embodiment, more than about 70% in yet another embodiment, more than about 80% in a further embodiment, or more than about 85% in still a further embodiment. In one embodiment, transparent layer 120 can be formed from a glass with about 90% transmittance, or more. Optionally, the substrate 110 can include a coating 126 applied to the first surface 122 of the transparent layer 120. The coating 126 can be configured to interact with light or to improve durability of the substrate 110 such as, but not limited to, an antireflective coating, an antisoiling coating, or a combination thereof.

Referring again to FIG. 2, the photovoltaic device 100 can include a barrier layer 130 configured to mitigate diffusion of contaminants (e.g., sodium) from the substrate 110, which could result in degradation or delamination. The barrier layer 130 can have a first surface 132 substantially facing the energy side 102 of the photovoltaic device 100 and a second surface 134 substantially facing the opposing side 104 of the photovoltaic device 100. In some embodiments, the barrier layer 130 can be provided adjacent to the substrate 110. For example, the first surface 132 of the barrier layer 130 can be provided upon the second surface 114 of the substrate 100. The phrase “adjacent to,” as used herein, means that two layers are disposed contiguously and without any intervening materials between at least a portion of the layers.

Generally, the barrier layer 130 can be substantially transparent, thermally stable, with a reduced number of pin holes and having high sodium-blocking capability, and good adhesive properties. Alternatively or additionally, the barrier layer 130 can be configured to apply color suppression to light. The barrier layer 130 can include one or more layers of suitable material, including, but not limited to, tin oxide, silicon dioxide, aluminum-doped silicon oxide, silicon oxide, silicon nitride, or aluminum oxide. The barrier layer 130 can have any suitable thickness bounded by the first surface 132 and the second surface 134, including, for example, more than about 100 Å in one embodiment, more than about 150 Å in another embodiment, or less than about 200 Å in a further embodiment.

Referring still to FIG. 2, the photovoltaic device 100 can include a transparent conductive oxide (TCO) layer 140 configured to provide electrical contact to transport charge carriers generated by the photovoltaic device 100. The TCO layer 140 can have a first surface 142 substantially facing the energy side 102 of the photovoltaic device 100 and a second surface 144 substantially facing the opposing side 104 of the photovoltaic device 100. In some embodiments, the TCO layer 140 can be provided adjacent to the barrier layer 130. For example, the first surface 142 of the TCO layer 140 can be provided upon the second surface 134 of the barrier layer 130. Generally, the TCO layer 140 can be formed from one or more layers of n-type semiconductor material that is substantially transparent and has a wide band gap. Specifically, the wide band gap can have a larger energy value compared to the energy of the photons of the light, which can mitigate undesired absorption of light. The TCO layer 140 can include one or more layers of suitable material, including, but not limited to, tin dioxide, doped tin dioxide (e.g., F—SnO₂), indium tin oxide, or cadmium stannate.

The photovoltaic device 100 can include a buffer layer 150 configured to provide an insulating layer between the TCO layer 140 and any adjacent semiconductor layers. The buffer layer 150 can have a first surface 152 substantially facing the energy side 102 of the photovoltaic device 100 and a second surface 154 substantially facing the opposing side 104 of the photovoltaic device 100. In some embodiments, the buffer layer 150 can be provided adjacent to the TCO layer 140. For example, the first surface 152 of the buffer layer 150 can be provided upon the second surface 144 of the TCO layer 140. The buffer layer 140 may include material having higher resistivity than the TCO later 140, including, but not limited to, intrinsic tin dioxide, zinc magnesium oxide (e.g., Zn₁₋ₓMgₓO), silicon dioxide (SnO₂), aluminum oxide (Al₂O₃), aluminum nitride (AlN), zinc tin oxide, zinc oxide, tin silicon oxide, or any combination thereof. In some embodiments, the material of the buffer layer 140 can be configured to substantially match the band gap of an adjacent semiconductor layer (e.g., an absorber). The buffer layer 150 may have any suitable thickness between the first surface 152 and the second surface 154, including, for example, more than about 100 Å in one embodiment, between about 100 Å and about 800 Å in another embodiment, or between about 150 Å and about 600 Å in a further embodiment.

Referring still to FIG. 2, the photovoltaic device 100 can include an absorber layer 160 configured to cooperate with another layer and form a p-n junction within the photovoltaic device 100. Accordingly, absorbed photons of the light can free electron-hole pairs and generate carrier flow, which can yield electrical power. The absorber layer 160 can have a first surface 162 substantially facing the energy side 102 of the photovoltaic device 100 and a second surface 164 substantially facing the opposing side 104 of the photovoltaic device 100. A thickness of the absorber layer 160 can be defined between the first surface 162 and the second surface 164. The thickness of the absorber layer 160 can be between about 0.5 μm to about 10 μm such as, for example, between about 1 μm to about 7 μm in one embodiment, or between about 1.5 μm to about 4 μm in another embodiment.

According to the embodiments described herein, the absorber layer 160 can be formed from a p-type semiconductor material having an excess of positive charge carriers, i.e., holes or acceptors. The absorber layer 160 can include any suitable p-type semiconductor material such as group II-VI semiconductors. Specific examples include, but are not limited to, semiconductor materials comprising cadmium, tellurium, selenium, or any combination thereof. Suitable examples include, but are not limited to, ternaries of cadmium, selenium and tellurium (e.g., CdSeₓTe₁₋ₓ), or a compound comprising cadmium, selenium, tellurium, and one or more additional element. The absorber layer 160 may further comprise one or more dopants. Photovoltaic devices may include a plurality of absorber materials.

In embodiments where the absorber layer 160 comprises tellurium and cadmium, the atomic percent of the tellurium can be greater than or equal to about 25 atomic percent and less than or equal to about 50 atomic percent such as, for example, greater than about 30 atomic percent and less than about 50 atomic percent in one embodiment, greater than about 40 atomic percent and less than about 50 atomic percent in a further embodiment, or greater than about 47 atomic percent and less than about 50 atomic percent in yet another embodiment. Alternatively or additionally, the atomic percent of the tellurium in the absorber layer 160 can be greater than about 45 atomic percent such as, for example, greater than about 49% in one embodiment. It is noted that the atomic percent described herein is representative of the entirety of the absorber layer 160, the atomic percentage of material at a particular location within the absorber layer 160 can vary with thickness compared to the overall composition of the absorber layer 160.

In embodiments where the absorber layer 160 comprises selenium and tellurium, the atomic percent of the selenium in the absorber layer 160 can be greater than about 0 atomic percent and less or equal to than about 25 atomic percent such as, for example, greater than about 1 atomic percent and less than about 20 atomic percent in one embodiment, greater than about 1 atomic percent and less than about 15 atomic percent in another embodiment, or greater than about 1 atomic percent and less than about 8 atomic percent in a further embodiment. It is noted that the concentration of tellurium, selenium, or both can vary through the thickness of the absorber layer 160. For example, when the absorber layer 160 comprises a compound including selenium at a mole fraction of x and tellurium at a mole fraction of 1-x (SeₓTe₁₋ₓ), x can vary in the absorber layer 160 with distance from the first surface 162 of the absorber layer 160.

Referring still to FIG. 2, the absorber layer 160 can be doped with a dopant configured to manipulate the charge carrier concentration. In some embodiments, the absorber layer 160 can be doped with a Group I or V dopant such as, for example, copper, arsenic, phosphorous, antimony, or a combination thereof. The total density of the dopant within the absorber layer 160 can be controlled. Alternatively or additionally, the amount of the dopant can vary with distance from the first surface 162 of the absorber layer 160. In some embodiments, dopants are introduced during a passivation step in the manufacturing process. Passivation may include, for example, treatment with CdCl₂ or other halide compounds, and resulting dopants may include chlorine or other halogens. Additionally, the amount of a selected dopant can vary with distance from the first surface 162 of the absorber layer 160.

According to the embodiments provided herein, the p-n junction can be formed by providing the absorber layer 160 sufficiently close to a portion of the photovoltaic device 100 having an excess of negative charge carriers, i.e., electrons or donors. In some embodiments, the absorber layer 160 can be provided adjacent to n-type semiconductor material. Alternatively, one or more intervening layers can be provided between the absorber layer 160 and n-type semiconductor material. In some embodiments, the absorber layer 160 can be provided adjacent to the buffer layer 150. For example, the first surface 162 of the absorber layer 160 can be provided upon the second surface 154 of the buffer layer 150.

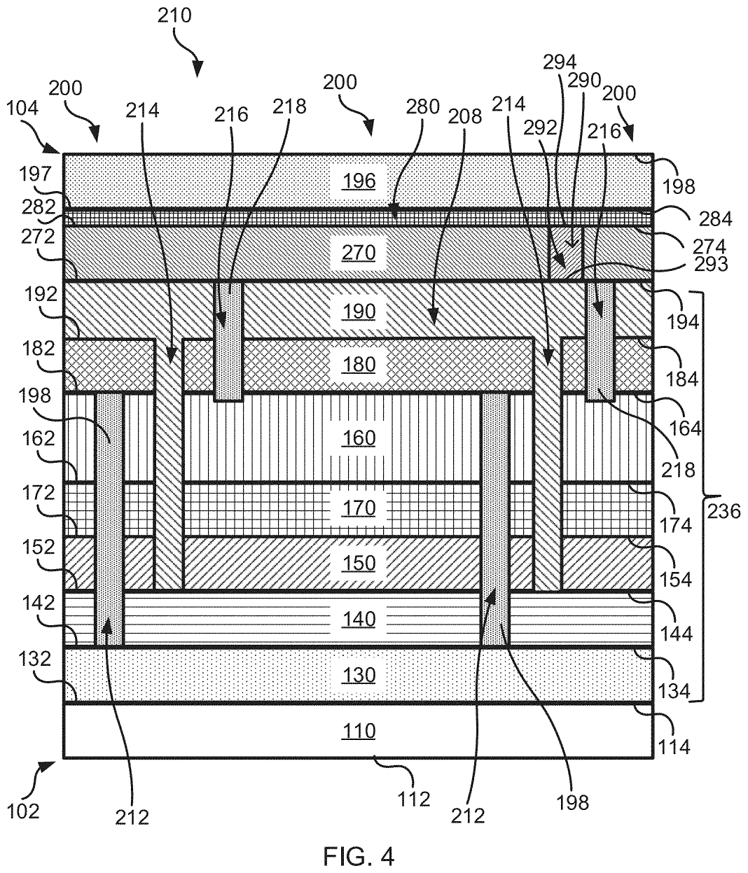

Referring now to FIG. 4, in some embodiments, a photovoltaic device 210 can include a window layer 170 comprising n-type semiconductor material. The absorber layer 160 can be formed adjacent to the window layer 170. The window layer 170 can have a first surface 172 substantially facing the energy side 102 of the photovoltaic device 100 and a second surface 174 substantially facing the opposing side 104 of the photovoltaic device 100. In some embodiments, the window layer 170 can be positioned between the absorber layer 160 and the TCO layer 20. In one embodiment, the window layer 170 can be positioned between the absorber layer 160 and the buffer layer 150. The window layer 170 can include any suitable material, including, for example, cadmium sulfide, zinc sulfide, cadmium zinc sulfide, zinc magnesium oxide, or any combination thereof. The material of the window layer 170 can include dopants.

Referring collectively to FIGS. 2 and 4, the photovoltaic device 100, 210 can include a back contact layer 180 configured to mitigate undesired alteration of the dopant and to provide electrical contact to the absorber layer 160. The back contact layer 180 can have a first surface 182 substantially facing the energy side 102 of the photovoltaic device 100 and a second surface 184 substantially facing the opposing side 104 of the photovoltaic device 100. A thickness of the back contact layer 180 can be defined between the first surface 182 and the second surface 184. The thickness of the back contact layer 180 can be between about 5 nm to about 200 nm such as, for example, between about 10 nm to about 50 nm in one embodiment.

In some embodiments, the back contact layer 180 can be provided adjacent to the absorber layer 160. For example, the first surface 182 of the back contact layer 180 can be provided upon the second surface 164 of the absorber layer 160. In some embodiments, the back contact layer 180 can include binary or ternary combinations of materials from Groups I, II, VI, such as for example, one or more layers containing zinc, copper, cadmium, and tellurium in various compositions. Further exemplary materials include, but are not limited to, zinc telluride doped with copper telluride, or zinc telluride alloyed with copper telluride.

The photovoltaic device 100 can include a conducting layer 190 configured to provide electrical contact with the absorber layer 160. The conducting layer 190 can have a first surface 192 substantially facing the energy side 102 of the photovoltaic device 100 and a second surface 194 substantially facing the opposing side 104 of the photovoltaic device 100. In some embodiments, the conducting layer 190 can be provided adjacent to the back contact layer 180. For example, the first surface 192 of the conducting layer 190 can be provided upon the second surface 184 of the back contact layer 180. The conducting layer 190 can include any suitable conducting material such as, for example, one or more layers of nitrogen-containing metal, silver, nickel, copper, aluminum, titanium, palladium, chrome, molybdenum, gold, or the like. Suitable examples of a nitrogen-containing metal layer can include aluminum nitride, nickel nitride, titanium nitride, tungsten nitride, selenium nitride, tantalum nitride, or vanadium nitride.

The photovoltaic device 100 can include a photovoltaic stack 236 that includes the layers on the substrate 110 through the conducting layer 190. The photovoltaic stack 236 can include the conductive layer 190, the back contact layer 180, the absorber layer 160, the buffer layer 150, the TCO layer 140, the barrier layer 130, and the window layer 170 (when present).

Referring collectively to FIGS. 2 and 4-6, the photovoltaic device 100, 210 can include an interlayer 270. The interlayer 270 can have a first surface 272 substantially facing the energy side 102 of the photovoltaic device 100 and a second surface 274 substantially facing the opposing side 104 of the photovoltaic device 100. In some embodiments, the interlayer 270 can be provided adjacent to the conducting layer 190. For example, the first surface 272 of the interlayer 270 can be provided upon the second surface 144 of the conducting layer 190.

The interlayer 270 may extend from the first side edge 306 to the second side edge 308 of the photovoltaic device 100. The interlayer 314 may be applied to extend over a portion of the photovoltaic stack 236, and may completely cover the photovoltaic stack 236 from the first side edge 306 to the second side edge 308. In this manner, the photovoltaic stack 236 is protected by the interlayer 314 during subsequent manufacturing processes, and is therefore less susceptible to being damaged from subsequent manufacturing steps.

The interlayer 270 may serve multiple functions. First, the interlayer 270 may serve as a moisture barrier between the back support 196 and the photovoltaic stack 236. By being a moisture barrier, the interlayer 270 may prevent moisture-induced corrosion from occurring inside the photovoltaic device 100. This, in turn, may increase the device's life expectancy. Second, the interlayer 270 may serve as an electrical insulator between the electrically conductive core of the photovoltaic device 100 and any accessible points exterior to the photovoltaic device 100. For example, the interlayer 270 may limit or prevent leakage current from passing from the back contact 190 through the back support 196 of the photovoltaic device 100. Third, the interlayer 270 may serve as a bonding agent that attaches the back support 196 to the rest of the photovoltaic device 100. During manufacturing, a lamination process may heat the interlayer 270 under vacuum to allow the material to wet-out any adjacent adherent surfaces, and in some cases initiate a cross-linking reaction. This process may promote bonding between the interlayer 270 and the back support 196 as well as between the interlayer 270 and the conducting layer 190. The interlayer 314, therefore, may serve as a bonding agent within the photovoltaic device 100. The lamination process can be from, e.g., about 100 to 175 degrees C. for about 15 to about 150 minutes. In one embodiment, the lamination process can be at about 115 to about 125 degrees C. for about 25 to about 35 minutes.

The interlayer 270 may include any suitable materials such as, for example, ethylene (EVA), polyvinyl butyral (PVB), polydimethylsiloxane (PDMS), polyiso-butylene (PIB), polyolefin, thermoplasatic polyurethane (TPU), polyurethane, epoxy, silicone, ionomer, or a combination thereof. In some embodiments, the interlayer 270 may include a base material and a filler material. The base material may be any of ethylene (EVA), polyvinyl butyral (PVB), polydimethylsiloxane (PDMS), polyiso-butylene (PIB), polyolefin, thermoplasatic polyurethane (TPU), polyurethane, epoxy, silicone, ionomer, or a combination thereof. The filler material can contain a flame retardant material, a dessicant material, a pigment, an inert material, or any combination thereof.

The interlayer 270 can include vias 290. The vias 290 can be poistionined in the interlayer 270 to permit access to the conductive layer 190. The position, spacing, and number of vias 290 in the interlayer 270 can be adjusted dependant on the desired output voltage of the photovoltaic device 100, 210. The vias 290 permit point contacts to the conductive layer 190. The vias 290 can contain a conductive compound 292.

The conductive compound 292 can be applied in the vias 290 to make a point contact to the conductive layer 190. The conductive compound 292 can have a first surface 293 substantially facing the energy side 102 of the photovoltaic device 100, 210 and a second surface 294 substantially facing the opposing side 104 of the photovoltaic device 100, 210. In some embodiments, the conductive compound 292 can be provided adjacent to the conducting layer 190 through the vias 290. For example, the first surface 293 of the conducting compound 292 can be provided upon the second surface 194 of the conducting layer 190. The conductive compound 292 can include an electrically conductive adhesive. The conductive compound 292 can be non-conductive when applied and activated in a later process. In one embodiment, a non-conductive adhesive is applied in the vias 290 and contacting the conductive layer 190 through the vias 290. The non-conductive adhesive is activated in a lamination process to form the conductive compound 292. The conductive compound 292 can have a conductivity of between, e.g., about 1×10³ S/m to about 6.3×10⁷ S/m. The conductive compound 292 can have a resistivity of between, e.g., about 1×10⁻⁶ Ωm to about 1.5×10⁻⁸ Ωm

The photovoltaic device 100, 210 can include a back support 196 configured to cooperate with the substrate 110 to form a housing for the photovoltaic device 100. The back support 196 can be disposed at the opposing side 104 of the photovoltaic device 100. The back support 196 can have a first surface 197 substantially facing the energy side 102 of the photovoltaic device 100 and a second surface 198 substantially facing the opposing side 104 of the photovoltaic device 100. For example, the back support 196 can be formed adjacent to the interlayer 270. For example, the first surface 197 of the back support 196 can be provided upon the second surface 274 of the interlayer 270. The back support 196 can include any suitable material, including, for example, glass (e.g., soda-lime glass). In some embodiments, an encapsulation layer can also function as the back support 196.

The back support 196 can include a bus bar 280 configured to be operable to collect current generated by the plurality of photovoltaic cells 200. The bus bar 280 can have a first surface 282 substantially facing the energy side 102 of the photovoltaic device 100 and a second surface 284 substantially facing the opposing side 104 of the photovoltaic device 100. The bus bar 280 can be provided on the first surface 197 of the back support 196. For example, the second surface of the bus member 294 can be provided upon the first surface 197 of the back support 196. The bus member can be electrically coupled to the second surface 294 of the conducting compound 292 of at least one of the plurality of photovoltaic cells 200.

The bus bar 280 can include any suitable conducting material such as, for example, one or more layers of nitrogen-containing metal, silver, nickel, copper, aluminum, titanium, palladium, chrome, molybdenum, gold, or the like. Suitable examples of a nitrogen-containing metal layer can include aluminum nitride, nickel nitride, titanium nitride, tungsten nitride, selenium nitride, tantalum nitride, or vanadium nitride. In one embodiment, the bus bar 280 can include a foil tape applied to the back support 196. The bus bar 280 can include a transparent conductive oxide. The bus bar 280 can include one or more layers of suitable material, including, but not limited to, tin dioxide, doped tin dioxide (e.g., F—SnO₂), indium tin oxide, or cadmium stannate. In one embodiment, the bus bar 280 can be masked and sputtered onto the back support 196.

Referring collectively to FIGS. 2, 4, and 5, manufacturing of a photovoltaic device 100, 210 generally includes sequentially disposing functional layers or layer precursors in a “stack” of layers through one or more thin film deposition processes, including, but not limited to, sputtering, spray, evaporation, molecular beam deposition, pyrolysis, closed space sublimation (CSS), pulse laser deposition (PLD), chemical vapor deposition (CVD), electrochemical deposition (ECD), atomic layer deposition (ALD), or vapor transport deposition (VTD). In some embodiments, VTD may be preferred for greater throughput quality. Manufacturing may also include annealing and passivating steps.

Manufacturing of photovoltaic devices 100, 210 can further include the selective removal of the certain layers of the stack of layers, i.e., scribing, to divide the photovoltaic device into 100, 210 a plurality of photovoltaic cells 200. For example, the serial scribes 202 can comprise a first isolation scribe 212 (also referred to as a P1 scribe), a series connecting scribe 214 (also referred to as a P2 scribe), and a second isolation scribe 216 (also referred to as a P3 scribe). The first isolation scribe 212 can be formed to ensure that the TCO layer 140 is electrically isolated between cells 200. Specifically, the first isolation scribe 212 can be formed though the TCO layer 140, the buffer layer 150, and the absorber layer 160 of photovoltaic device 100, or though the TCO layer 140, the buffer layer 150, the window layer 170, and the absorber layer 160 of the photovoltaic device 210. The first isolation scribe 212 bounding the reverse operation cell 208 can be filled with a dielectric material 198.

Referring again to FIGS. 2 and 4, the series connecting scribe 214 can be formed to electrically connect photovoltaic cells 200 in series. For example, the series connecting scribe 214 can be utilized to provide a conductive path from the conductive layer 190 of one of the photovoltaic cells 200 to the TCO layer 140 of another of the photovoltaic cells 200. The series connecting scribe 214 can be formed through the absorber layer 160, and the back contact layer 180 of photovoltaic device 100, or through the window layer 170, the absorber layer 160, and the back contact layer 180 of the photovoltaic device 210. Optionally, the series connecting scribe 214 can be formed through some or all of the buffer layer 150. Accordingly, the series connecting scribe 214 can be formed after the back contact layer 180 is deposited. The series connecting scribe 214 can then be filled with a conducting material such as, but not limited to, the material of the conducting layer 190. In some embodiments, the conductive material can be more conductive in reverse bias relative to forward bias.

The second isolation scribe 216 can be formed to isolate the back contact 190 into individual cells 200. The second isolation scribe 216 can be formed through the conductive layer 190, the back contact layer 180, and at least a portion of the absorber layer 160. The second isolation scribe 216 can be filled with a dielectric material 218.

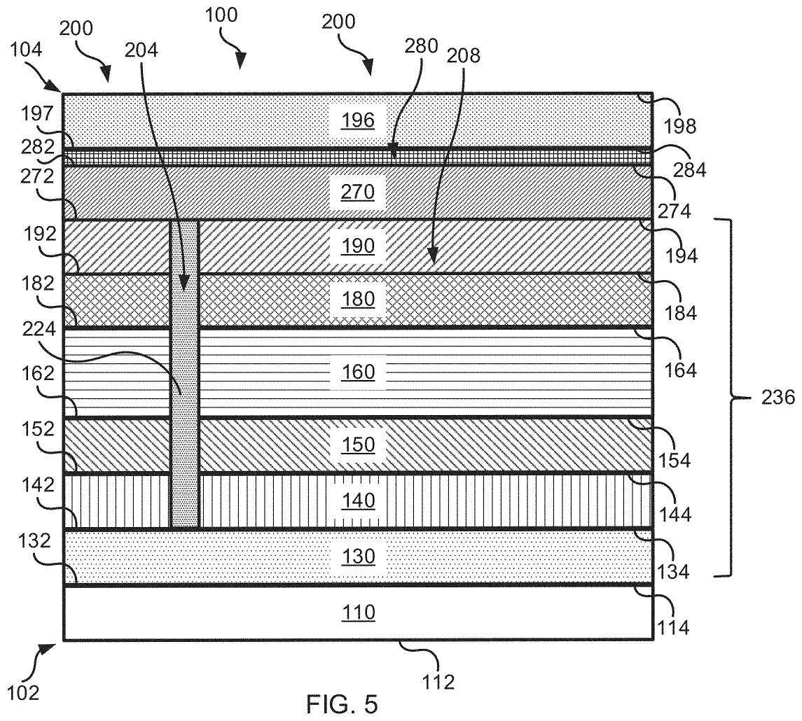

Referring collectively to FIGS. 1 and 5, a parallel scribe 204 (also referred to as a P4 scribe) can be formed to isolate groups 206 of cells 200 from one another. In some embodiments, each group 206 can comprise multiple photovoltaic cells 200 connected in series such as, for example, via the series connecting scribe 214. The parallel scribe 204 can be formed through the conductive layer 190, the back contact layer 180, the absorber layer 160, the buffer layer 150, the TCO layer 140, the barrier layer 130, and the window layer 170 (when present). According to the embodiments provided herein, each of the parallel scribe 204, the first isolation scribe 212, the series connecting scribe 214, and the second isolation scribe 216 can be formed via laser cutting or laser scribing. In some embodiments, the parallel scribe 204 can be filled with a dielectric material.

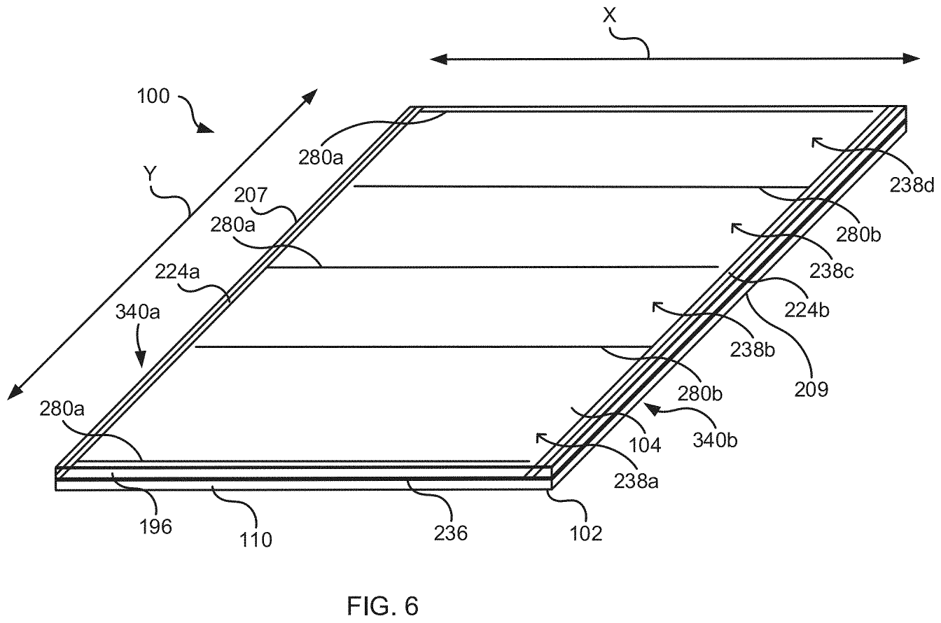

Referring to FIGS. 1 and 6, an embodiment of a photovoltaic device 100 is schematically depicted. The photovoltaic device 100 can be configured to receive light and transform light into electrical signals, e.g., photons can be absorbed from the light and transformed into electrical signals via the photovoltaic effect. Accordingly, the photovoltaic device 100 can define the energy side 102 configured to be exposed to a light source such as, for example, the sun. The photovoltaic device 100 can also define the opposing side 104 offset from the energy side 102 such as, for example, by a plurality of material layers.

The photovoltaic device 100 can include a plurality of layers disposed between the energy side 102 and the opposing side 104. The photovoltaic device 100 can include the substrate 110 on the energy side 102, the photovoltaic stack 236, and the back support 296 on the opposing side 104. As used herein, the term “layer” refers to a thickness of material provided upon a surface. Each layer can cover all or any portion of the surface. In some embodiments, the layers of the photovoltaic device 100 can be divided into an array of photovoltaic cells 200. For example, the photovoltaic device 100 can be scribed according to a plurality of serial scribes 202 and a plurality of parallel scribes 204. Accordingly, the serial scribes 202 and the parallel scribes 204 can demarcate the array of the photovoltaic cells 200.

The parallel scribes 204 can electrically isolate the groups 238 of photovoltaic cells 200 that are connected serially. In some embodiments, the groups 238 of the photovoltaic cells 200 can be connected in parallel such as, for example, via electrical bussing. Optionally, the number of parallel scribes 204 can be configured to limit a maximum current generated by each group 238 of the photovoltaic cells 200. In some embodiments, the maximum current generated by each group 238 can be less than or equal to about 500 milliamps (mA) such as, for example, less than or equal to about 100 mA in one embodiment, less than or equal to about 75 mA in another embodiment, or less than or equal to about 50 mA in a further embodiment. The parallel scribes 204 and the serial scribes 202 can be configured to isolate the groups 238 for a designed voltage. These plurality of scribes permits the photovoltaic device to support voltages from, e.g., about 25 V to about 600V. The lower voltage groups permit the photovoltaic device 100 to produce a higher current. The voltage is configured by dividing the photovoltaic device 100 into the groups 238. In some embodiments, the photovoltaic device 100 can be divided into, e.g., 2 groups, 3 groups, 4 groups, 5 groups, 8 groups. 16 groups, etc. In one embodiment, the photovoltaic device 100 is divided into 4 groups. Groups 238a, 238b, 238c, and 238d can have the same voltage or different voltages, dependent on the configuration of the plurality of serial scribes 202 and the plurality of parallel scribes 204.

The photovoltaic device 100 may have a first peripheral edge 340a on a first side 207 with a first bus member 224a extending along the length Y and a first bus bar 280a extending from the first bus member 224a along the width X, and a second peripheral edge 340b on an opposing second side 209 with a second bus member 224b extending along the length Y and a second bus bar 280b extending from the second bus member 224b along the width X. In one embodiment, the bus member 224a near the first peripheral edge 340a may act as a positive bus, and a second bus member 224b near the second peripheral edge 340b may act as a negative bus.

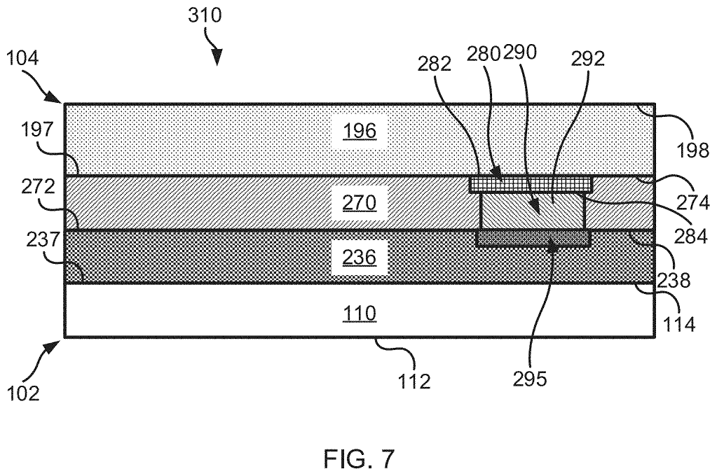

Referring to FIG. 7, an embodiment of a photovoltaic device 310 is schematically depicted. The layers of the photovoltaic device 310 can include a substrate 110 configured to facilitate the transmission of light into the photovoltaic device 100. The substrate 110 can be disposed at the energy side 102 of the photovoltaic device 100. The substrate 110 can have a first surface 112 substantially facing the energy side 102 of the photovoltaic device 100 and a second surface 114 substantially facing the opposing side 104 of the photovoltaic device 100. One or more layers of material can be disposed between the first surface 112 and the second surface 114 of the substrate 110.

The photovoltaic device 100 can include the photovoltaic stack 236. The photovoltaic stack 236 can include the conductive layer 190, the back contact layer 180, the absorber layer 160, the buffer layer 150, the TCO layer 140, the barrier layer 130, and the window layer 170 (when present), amongst other layers. The photovoltaic stack 236 can have a first surface 237 substantially facing the energy side 102 of the photovoltaic device 310 and a second surface 238 substantially facing the opposing side 104 of the photovoltaic device 310. For example, the first surface 237 of the photovoltaic stack 236can be provided upon the second surface 114 of the substrate 110. The photovoltaic stack 236 can include a latch cell 295. The latch cell 295 is a current collection point for the photovoltaic device 310. In one embodiment, the latch cell 295 can be on the second surface 238 of the photovoltaic stack.

The photovoltaic device 310 can include an interlayer 270. The interlayer 270 can have a first surface 272 substantially facing the energy side 102 of the photovoltaic device 310 and a second surface 274 substantially facing the opposing side 104 of the photovoltaic device 310. In some embodiments, the interlayer 270 can be provided adjacent to the photovoltaic stack 236. For example, the first surface 272 of the interlayer 270 can be provided upon the second surface 238 of the photovoltaic stack 236.

The interlayer 270 can include vias 290. The vias 290 can be poistionined in the interlayer 270 to permit access to the latch cell 295. The positioin , spacing, and number of vias 290 in the interlayer 270 can be adjusted dependant on the desired output voltage of the photovoltaic device 310. The vias 290 permit point contacts to the latch cell 295. The vias 290 can contain a conductive compound 292.

The conductive compound 292 can have a first surface 293 substantially facing the energy side 102 of the photovoltaic device 310 and a second surface 294 substantially facing the opposing side 104 of the photovoltaic device 310. In some embodiments, the conductive compound 292 can be provided adjacent to the latch cell 295through the vias 290. For example, the first surface 293 of the conducting compound 292 can be provided upon the second surface 238 of the photovoltaic stack 236, where the second surface 238 of the photovoltaic stack 236 includes the latch cell 295. The conductive compound 292 can include an electrically conductive adhesive. The conductive compound 292 can be non-conductive when applied and activated in a later process. In one embodiment, a non-conductive adhesive is applied in the vias 290 and contacting the latch cell 295 through the vias 290. The non-conductive adhesive is activated in a lamination process to form the conductive compound 292. The conductive compound 292 can have a conductivity of between, e.g., about 1×10³ S/m to about 6.3×10⁷ S/m.

The photovoltaic device 310 can include a back support 196 configured to cooperate with the substrate 110 to form a housing for the photovoltaic device 100. The back support 196 can be disposed at the opposing side 104 of the photovoltaic device 100. The back support 196 can have a first surface 197 substantially facing the energy side 102 of the photovoltaic device 100 and a second surface 198 substantially facing the opposing side 104 of the photovoltaic device 100. For example, the back support 196 can be formed adjacent to the interlayer 270. For example, the first surface 197 of the back support 196 can be provided upon the second surface 274 of the interlayer 270. The back support 196 can include any suitable material, including, for example, glass (e.g., soda-lime glass). In some embodiments, an encapsulation layer can also function as the back support 196.

The back support 196 can include a bus bar 280 configured to be operable to collect current generated by the photovoltaic device 310. The bus bar 280 can have a first surface 282 substantially facing the energy side 102 of the photovoltaic device 100 and a second surface 284 substantially facing the opposing side 104 of the photovoltaic device 100. The bus bar 280 can be provided on the first surface 197 of the back support 196. For example, the second surface of the bus member 294 can be provided upon the first surface 197 of the back support 196. The bus member can be electrically coupled to the second surface 294 of the conducting compound 292. The bus bar 280 can be electrically coupled to the latch cell 295 through the conductive compound 290.

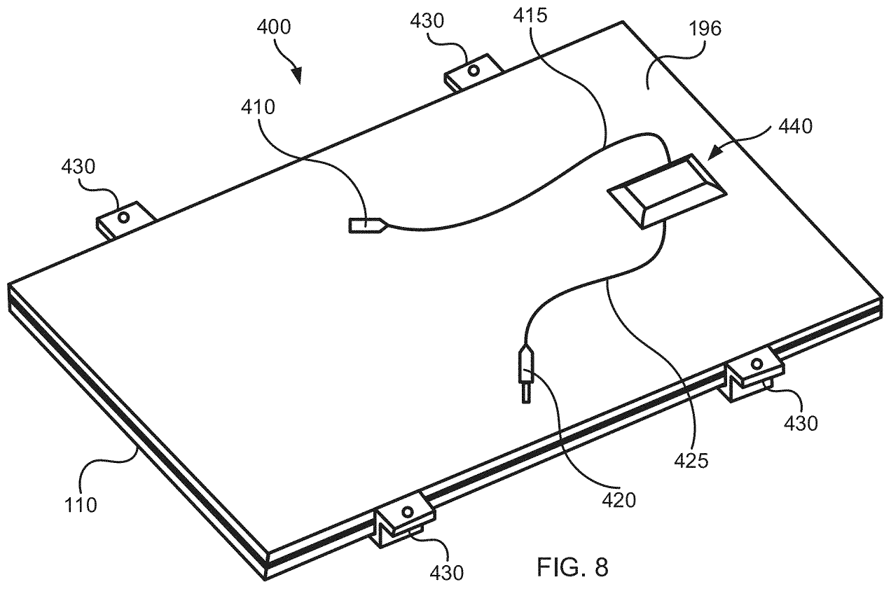

After the layer stack with scribes is formed, bussing on the back support 196 may be added as described above, and the photovoltaic device may be assembled. An encapsulation layer may be applied and the semiconductor layers may be sealed relative to rain, snow, and other metrological elements. Referring now to FIG. 8, the substrate 110 and the back support 196 may be laminated together so as to encapsulate the photovoltaic cells 200. The substrate 110 has a width and a length and the back support 196 may have substantially the same width and length as the substrate 110. Each of the substrate 110 and the back support 196 can include any suitable protective material such as, for example, borosilicate glass, float glass, soda lime glass, carbon fiber, or polycarbonate. Alternatively, the back support 196 may be any suitable material such as a polymer-based back sheet. The back support 196 and substrate 110 can protect the various layers of the photovoltaic device 100 from exposure to moisture and other environmental hazards. FIG. 8 shows a perspective view of the back side of an example of a completed module. The module assembly 400 may include the layers described and depicted in FIGS. 1-7, as well as encapsulation and electrical connectors. The photovoltaic module assembly 400 may be configured to connect to a load through electrical connectors which pass through the junction box 440. The electrical connectors may include a first cable 415 with a first terminal 410, and a second cable 425 with a second terminal 420. The module assembly 400 may further include a supporting frame, bracket, or mount 430.

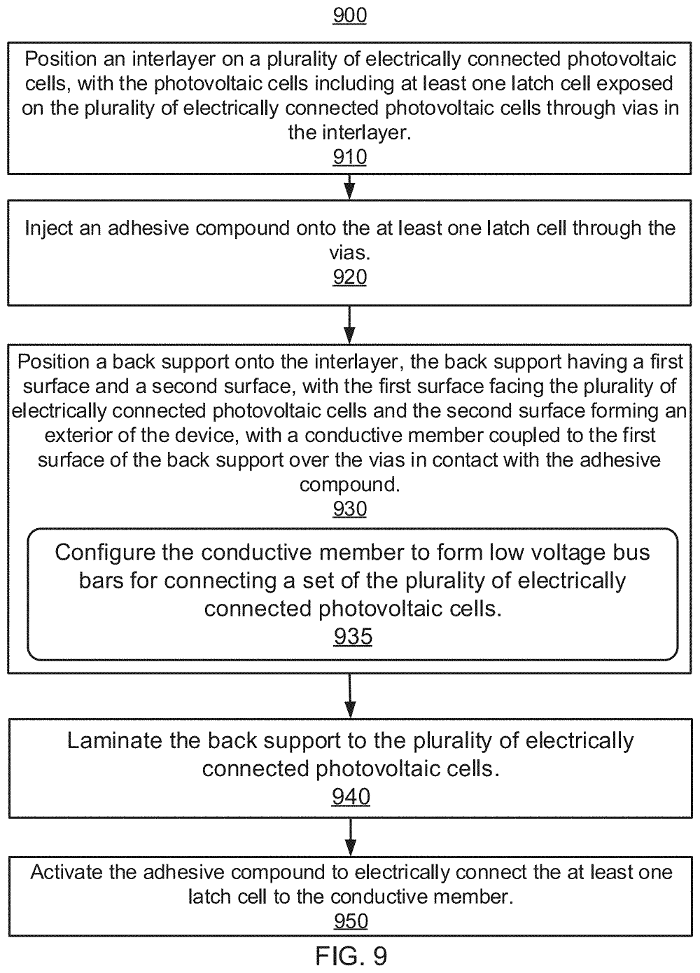

Referring now to FIG. 9, a flow diagram illustrating a method 900 for manufacturing a photovoltaic device. In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

In block 910, an interlayer is positioned on a plurality of electrically connected photovoltaic cells, with the photovoltaic cells including at least one latch cell exposed on the plurality of electrically connected photovoltaic cells through vias in the interlayer. In block 920, an adhesive compound is injected onto the at least one latch cell through the vias. In block 930, a back support is positioned onto the interlayer, the back support having a first surface and a second surface, with the first surface facing the plurality of electrically connected photovoltaic cells and the second surface forming an exterior of the device, with a conductive member coupled to the first surface of the back support over the vias in contact with the adhesive compound. In block 935, the conductive member is configured to form low voltage bus bars for connecting a set of the plurality of electrically connected photovoltaic cells. In block 940, the back support is laminated to the plurality of electrically connected photovoltaic cells. In block 950, the adhesive compound is activated to electrically connect the at least one latch cell to the conductive member

According to embodiments described herein, a photovoltaic device can include a plurality of electrically connected photovoltaic cells. The photovoltaic cells can include at least one latch cell. The photovoltaic device can include an interlayer over the plurality of electrically connected photovoltaic cells. The interlayer can include vias exposing the at least one latch cell in the plurality of electrically connected photovoltaic cells. A back support can be over the interlayer. The back support having a first surface and a second surface, with the first surface facing the plurality of electrically connected photovoltaic cells and the second surface forming an exterior of the device. The back support can include a conductive member coupled to the first surface of the back support. The photovoltaic device can include an activated adhesive compound electrically connecting the at least one latch cell to the conductive member through the vias.

According to embodiments described herein, a photovoltaic device can include foil tape as a conductive member.

According to embodiments described herein, a photovoltaic device can include a sputtered on conductive compound as a conductive member.

According to embodiments described herein, a photovoltaic device can include a translucent conductive oxide as a conductive member.

According to embodiments described herein, a photovoltaic device can include a translucent back support.

According to embodiments described herein, a photovoltaic device can include an activated adhesive compound with a resistance under about 0.01 Ohms.

According to embodiments described herein, a photovoltaic device can include a conductive member configured to form low voltage bus bars connecting a set of a plurality of electrically connected photovoltaic cells.

According to embodiments described herein, a photovoltaic device can include a set of a plurality of electrically connected photovoltaic cells connected together in parallel with a low voltage bus bar.

According to embodiments described herein, a method for manufacturing a photovoltaic device can include positioning an interlayer on a plurality of electrically connected photovoltaic cells. The photovoltaic cells including at least one latch cell exposed on the plurality of electrically connected photovoltaic cells through vias in the interlayer. Injecting an adhesive compound onto the at least one latch cell through the vias. Positioning a back support onto the interlayer. The back support having a first surface and a second surface, with the first surface facing the plurality of electrically connected photovoltaic cells and the second surface forming an exterior of the device. The back support including a conductive member coupled to the first surface of the back support over the vias in contact with the adhesive compound. Activating the adhesive compound to electrically connect the at least one latch cell to the conductive member.

According to embodiments described herein, a method for manufacturing a photovoltaic device can include activating an adhesive compound utilizing a thermal process.

According to embodiments described herein, a method for manufacturing a photovoltaic device can include laminating a back support to a plurality of electrically connected photovoltaic cells.

According to embodiments described herein, a method for manufacturing a photovoltaic device can include activating an adhesive compound while laminating a back support to a plurality of electrically connected photovoltaic cells.

According to embodiments described herein, a method for manufacturing a photovoltaic device can include sputtering a conductive member onto a back support.

According to embodiments described herein, a method for manufacturing a photovoltaic device can include configuring a conductive member to form low voltage bus bars for connecting a set of a plurality of electrically connected photovoltaic cells.

Certain embodiments of the devices and methods disclosed herein are defined in the above examples. It should be understood that these examples, while indicating particular embodiments, are given by way of illustration only. From the above discussion and these examples, one skilled in the art can ascertain the essential characteristics of this disclosure, and without departing from the spirit and scope thereof, can make various changes and modifications to adapt the devices and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A photovoltaic device comprising:
a plurality of electrically connected photovoltaic cells, wherein the photovoltaic cells include at least one latch cell;
an interlayer over the plurality of electrically connected photovoltaic cells, wherein the interlayer includes vias exposing the at least one latch cell in the plurality of electrically connected photovoltaic cells;
a back support over the interlayer, the back support having a first surface and a second surface, with the first surface facing the plurality of electrically connected photovoltaic cells and the second surface forming an exterior of the device, with a conductive member coupled to the first surface of the back support; and
an activated adhesive compound electrically connecting the at least one latch cell to the conductive member through the vias.

2. The photovoltaic device of claim 1, wherein the conductive member comprises foil tape.

3. The photovoltaic device of claim 1, wherein the conductive member comprises a sputtered on conductive compound.

4. The photovoltaic device of claim 3, wherein the conductive compound is a translucent conductive oxide.

5. The photovoltaic device of claim 1, wherein the back support comprises a translucent material.

6. The photovoltaic device of claim 1, wherein the activated adhesive compound has a resistivity under about 1×10⁻⁶ Ωm.

7. The photovoltaic device of claim 1, wherein the conductive member is configured to form low voltage bus bars connecting a set of the plurality of electrically connected photovoltaic cells.

8. The photovoltaic device of claim 7, wherein the low voltage bus bar connects each of the set of the plurality of electrically connected photovoltaic cells together in parallel.

9. A method for manufacturing a photovoltaic device comprising:
positioning an interlayer on a plurality of electrically connected photovoltaic cells, with the photovoltaic cells including at least one latch cell exposed on the plurality of electrically connected photovoltaic cells through vias in the interlayer;
injecting an adhesive compound onto the at least one latch cell through the vias;
positioning a back support onto the interlayer, the back support having a first surface and a second surface, with the first surface facing the plurality of electrically connected photovoltaic cells and the second surface forming an exterior of the device, with a conductive member coupled to the first surface of the back support over the vias in contact with the adhesive compound;
activating the adhesive compound to electrically connect the at least one latch cell to the conductive member.

10. The method of claim 9, wherein activating the adhesive compound utilizes a thermal process.

11. The method of claim 9, further comprising laminating the back support to the plurality of electrically connected photovoltaic cells.

12. The method of claim 11, wherein the laminating of the back support to the plurality of electrically connected photovoltaic cells activates the adhesive compound.

13. The method of claim 9, further comprising sputtering the conductive member onto the back support.

14. The method of claim 9, further comprising configuring the conductive member to form low voltage bus bars for connecting a set of the plurality of electrically connected photovoltaic cells.

15. The photovoltaic device of claim 2, wherein the conductive member comprises a sputtered on conductive compound.

16. The photovoltaic device of claim 15, wherein the conductive compound is a translucent conductive oxide.
